(19) United States
(12) Patent Application Publication
(10) Pub. No.: US 2026/0319033 A1
(43) Pub. Date: Oct. 15, 2026

(54) MAGNETOMETER UNIT WITH MAGNETIC FIELD MODULATION FOR DIRECTION-SENSITIVE MEASUREMENT OF A MAGNETIC FIELD, AND GRADIOMETER UNIT WITH MAGNETOMETER UNIT

(71) Applicant: Robert Bosch GmbH, Stuttgart (DE)

(72) Inventors: Timo Weggler, Ulm (DE); Andreas Brenneis, Renningen (DE); Eckhard Wehrse, Stuttgart (DE)

(21) Appl. No.: 19/117,191

(22) PCT Filed: Oct. 25, 2023
(86) PCT No.: PCT/EP2023/079743

§ 371 Date: Mar. 31, 2025

(30) Foreign Application Priority Data
Nov. 9, 2022 (DE) 10 2022 211 859.6

(51) Int. Cl. G01R 33/26

(52) U.S. Cl. CPC G01R 33/26

(57) ABSTRACT

A magnetometer unit for measuring a magnetic field. The magnetometer unit includes a sensor medium exposed to the magnetic field to be measured, an excitation light source for irradiating light into the sensor medium, a microwave source for generating an electromagnetic field in the sensor medium, and a device for generating a bias magnetic field in the region of the sensor medium. The magnetometer unit is configured to measure a magnetic field strength and direction of the magnetic field to be measured, by reading out a spin resonance in the sensor medium that is dependent on the magnetic field strength and direction. The device for generating a bias magnetic field is configured to generate a bias magnetic field having a constant component and a time-varying component.

### FIELD

The present invention relates to a magnetometer unit for measuring a magnetic field and to a gradiometer unit with at least two such magnetometer units.

### BACKGROUND INFORMATION

Optically pumped quantum sensors or quantum sensors based on NV centers in diamonds are in particular suitable as sensors for measuring very small magnetic field strengths. German Patent Application No. DE 10 2022 204 526.2 describes a magnetometer that uses optically pumped and optically detected magnetic resonance (ODMR). It utilizes the fact that the energy levels of certain spin states of unpaired electrons are split under the influence of an external magnetic field, the so-called Zeeman effect. Splitting of the energy levels results in changed transitions during relaxation from excited states, which can then be measured, for example, by optical excitation and frequency-dependent detection of the resulting fluorescence radiation or by observation of optical properties such as the absorption of light. From the measured optical parameters, the magnetic field strength can then in turn be deduced.

### SUMMARY

According to the present invention, a magnetometer unit for measuring a magnetic field and a gradiometer unit with at least two such magnetometer units are provided. Advantageous example embodiments of the present invention are disclosed herein.

According to an example embodiment of the present invention, the magnetometer unit for measuring a magnetic field includes a sensor medium exposed to the magnetic field to be measured, an excitation light source for irradiating light into the sensor medium, a microwave source for generating an electromagnetic field in the sensor medium, and a device for generating a bias magnetic field in the region of the sensor medium. The magnetometer unit is configured to detect a magnetic field strength and direction of the magnetic field to be measured, by reading out a spin resonance in the sensor medium that is dependent on the magnetic field strength and direction. For reading out, a photodetector for detecting fluorescent light from the sensor medium or a photocurrent detector may be used, for example.

In one example embodiment of the present invention, the sensor medium has a diamond crystal or a portion of a diamond crystal with nitrogen-vacancy (NV) centers. Diamond NV magnetometers are based on reading out the magnetic resonances of specific defect centers in diamonds, in particular nitrogen vacancies, which occur as impurities in the carbon lattice of diamonds and can also be introduced in a targeted manner. If the NV center is optically excited in the ground state, e.g., by irradiating a pump laser beam having a suitable wavelength (in this case in the green wavelength range, e.g., at 532 nm for off-resonance excitation), the electrons are raised from the triplet ground state to the excited triplet state and relax while emitting fluorescent light in the red wavelength range at 650-800 nm (637 nm=zero phonon line). Since the probability of non-spin-conserving transitions from the spin state with spin quantum number mₛ=±1 is higher, continuous excitation pumping ensures that the NV centers are largely hyperpolarized in the spin state mₛ=0.

Between the mₛ=0 and mₛ=±1 spin states in the ground state, there is an energy difference, which in this case is about 2.87 GHz. Thus, if microwave radiation is irradiated into the diamond in addition to the optical excitation, there is a drop in the red fluorescence at this resonance frequency of 2.87 GHZ since the spin-polarized electrons are raised by the microwave field from the mₛ=0 to the mₛ=±1 ground state and excited from there by the pump light to the mₛ=±1 excited state. From there, however, primarily non-radiative transitions and weak infrared fluorescence transitions occur via the singlet state, while the fluorescence in the red range ceases.

If an external magnetic field (to be measured) is present, the so-called Zeeman effect results in splitting of the otherwise isoenergetic mₛ=±1 triplet levels into energetically equidistant Zeeman levels. Plotting the fluorescence over a frequency spectrum of the microwave excitation then reveals two drops in the fluorescence spectrum, the frequency spacing of which is proportional to the magnetic field strength of the external magnetic field. The magnetic field sensitivity is primarily defined by the minimally resolvable frequency shift and can reach 1 pT/√Hz or less. Since the NV center in a monocrystalline diamond can be arranged in four possible ways in the crystal lattice, the presence of an additional bias magnetic field causes the NV centers present in the crystal to react differently to the external magnetic field depending on their position in the crystal. As a result, four pairs of fluorescence minima may ideally appear in the spectrum, from the shapes and relative positions of which both the magnetic field strength as a magnitude and the direction of the external magnetic field can be determined unambiguously.

In order to make magnetic field measurements possible, the magnetometer unit therefore comprises the device for generating the bias magnetic field in the region of the sensor medium. This device may be a Helmholtz coil assembly, wherein at least the sensor medium is arranged within the Helmholtz coil assembly. It may also be another device, such as a simple coil, an elongated coil, a permanent magnet arrangement, such as in a Hallbach array, etc. In order additionally to be able to determine vectorial (direction-dependent) magnetic information, a defined direction of the bias magnetic field is needed.

It has been found that, when a constant bias magnetic field is applied, in certain situations, an ambiguity of the determination of direction may occur, i.e., a distinction between the directions along or against the applied static bias magnetic field(s) cannot be made. It is therefore proposed that the bias magnetic field has a constant component and a time-varying component. Adding a variable component to the static bias magnetic field makes it possible to distinguish the direction of the magnetic field vector to be measured. The determination of the direction of a magnetic field can thus be ensured.

At least the time-varying component can be generated very simply by varying a current through one or more coils, e.g., by means of a modulable current driver.

In one example embodiment of the present invention, an amplitude of the time-varying component is less than 50%, in particular at most 108, or at most 20%, or at most 30%, of an amplitude of the constant component. Thus, the bias magnetic field is in particular not reversed and, further in particular, determined mainly by the static component.

In one example embodiment of the present invention, the time-varying component follows a periodic function, in particular a sine function. This facilitates evaluation, in particular if, in addition, a fundamental frequency of the time-varying component is at least 10 Hz and/or at most 10 kHz.

When a gradiometer circuitry of at least two magnetometer units is used, one magnetometer unit is always further away from the magnetic field source than another magnetometer unit. Due to the gradiometer circuitry, i.e., substantially (vectorial) subtraction of what is measured, the magnetic field gradient approximately corresponds to the field originating from the weak source, while substantially stronger background fields (which are substantially the same in the two magnetometer units) are eliminated. This eliminates the need for magnetic shielding so that magnetic field measurement in everyday environments becomes possible. Accordingly, the present invention is in particular suitable for non-shielded measurement of weak magnetic fields. Technical details for gradiometer configurations that can also be used within the framework of the present invention are described in German Patent Application No. DE 10 2022 201 690.4 and are to be incorporated here.

In one example embodiment of the present invention, the sensor medium of the magnetometer units of the gradiometer unit can in each case comprise a portion of the same diamond crystal. In this design, in addition to compactness, it is also ensured that the two portions used as the sensor medium have substantially the same properties and thus also exhibit the same optical properties when reading out the spin resonance, so that no error sources in the difference formation of the gradiometer are created. In one embodiment, the same excitation light source and/or the same microwave source are used for the magnetometer units of the gradiometer unit. In this way, fluctuations and noise components from these elements are automatically eliminated by the differential signal formation (common noise rejection).

Further advantages and embodiments of the present invention emerge from the description herein and the figures.

The present invention is shown schematically in the figures on the basis of exemplary embodiments and is described in detail below with reference to the figures.

### BRIEF DESCRIPTION OF THE DRAWINGS

FIG. 1 shows a schematic block view of the essential components of an NV center magnetometer as may be used within the framework of the present invention.

FIG. 2 schematically shows two magnetic fields that cannot be distinguished when a static bias magnetic field is not used according to the present invention.

FIG. 3 shows the curve of measurement signals for oppositely aligned magnetic fields when measured according to one embodiment of the present invention.

### DETAILED DESCRIPTION OF EXAMPLE EMBODIMENTS

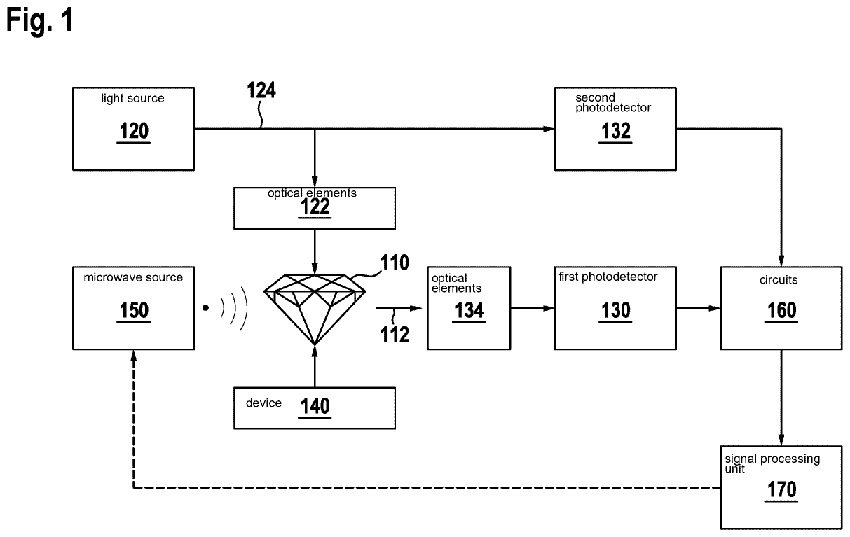

FIG. 1 schematically shows the main components of an NV center magnetometer according to one example embodiment of the present invention. First, a diamond 110 with nitrogen vacancies (NV) is present as the sensor medium. Optical excitation of the NV centers can be achieved by means of a suitable light source 120 such as a pump laser. Here, for example, a frequency-doubled Nd: YAG laser or semiconductor laser in the green range of about 510-532 nm, e.g., at 532 nm, is suitable for off-resonance excitation. Alternatively, LEDs in suitable wavelength ranges may also be used. Depending on the arrangement, the light of the light source 120 may be irradiated into the diamond 110 via suitable optical elements 122, such as mirrors, beam splitters, focusing optics such as lenses, and optionally via fiber-optic elements. In addition, the excitation light may be irradiated continuously or in a pulsed manner by the laser so that, for example, time windows for interference-free fluorescent light measurement are kept clear.

Furthermore, the magnetometer may comprise a microwave source 150 capable of generating, in the sensor medium, an electromagnetic field across a bandwidth that covers the desired resonance frequency, i.e., in the range of the NV centers of the diamond 110. A microwave resonator structure may be used to distribute the generated microwaves homogeneously over the volume of the measurement region in the diamond. The resonator structure or the microwave source 150 is preferably tuned to the frequency of the electron spin resonances. In order to make vector magnetometry possible, an additional bias magnetic field is generated by means of a device 140. As a result, the measurement becomes intrinsically vectorial. Different spatial directions are used in the crystal structure for this purpose. For example, a Helmholtz coil in which a substantially homogeneous magnetic field can be generated in a limited region by means of a pair of coils is suitable for generating such a magnetic field. The device may also be another device 140, such as a simple coil, an elongated coil, a permanent magnet arrangement, such as in a Hallbach array, etc.

The resulting fluorescent light 112 from the diamond 110 may in turn be directed via suitable optical elements 134, such as optical filters, beam splitters, lenses, and/or fiber-optic elements to a first photodetector 130 that is sensitive at least in the range of the fluorescence wavelength. The first photodetector 130 may also be arranged directly on the diamond 110. A second photodetector 132 is arranged such that it can detect at least a portion of the excitation light of the light source 120, which may be coupled out, for example, by a beam splitter, a filter, or a partially transparent element. This detector signal 132 of the excitation light can be used as a reference signal to eliminate background signals, for example, by modulating the excitation light by means of a lock-in amplifier and to highlight the resonance signal of interest. Additionally, or alternatively, this reference signal may be used to take fluctuations of the excitation light into account. Corresponding circuits 160, such as a preamplifier, logarithmic amplifier, lock-in amplifier, signal filters, or others, are thus provided to receive the signals of the first and second photodetectors and to pre-process the signals appropriately for further evaluation. Finally, the pre-processed fluorescence signal can be evaluated by a signal processing unit 170, e.g., with a suitable microcontroller or processor, in order to obtain the desired parameters of the detected magnetic field from the signal, in particular the magnetic field strength and the direction of the magnetic field.

It is understood that such a device may also comprise further units not shown, such as communication units or interfaces for outputting the measurement results. Such a device may also be advantageously integrated into an ASIC or FPGA.

The NV center magnetometer provides a variety of advantages for the present application. In addition to the very high sensitivity mentioned above, a high measurement range (>1 tesla) can also be covered. The underlying Zeeman effect is linearly dependent on the magnetic field present and also does not show any degradation since the measurement is based on quantum mechanical states. In addition, an NV center magnetometer provides the possibility of determining external magnetic fields vectorially on the basis of the different alignments present in the diamond lattice.

There are also alternative ways to read out the magnetic spin resonance in the diamond electrically. Charge carriers that were raised into the diamond conduction band by two-photon ionization of the NV centers are detected in this case. If such a method is used to read out the resonance effects, the parts for detecting the fluorescent light in the previous examples are not required and are replaced by suitable photocurrent detectors on the diamond. However, apart therefrom, the method for magnetic field measurement can be transferred accordingly and can be used in all embodiments with NV center magnetometers.

In order to be usable in an everyday environment, magnetic fields not originating from desired weak sources are to be eliminated from the measurement as far as possible, in particular the Earth's magnetic field in the range of 10⁻⁵ tesla (several microtesla).

The elimination of the background magnetic fields may be achieved by a shield or by a gradiometer arrangement for the magnetic field measurement according to exemplary embodiments. Gradiometers are basically magnetometer units capable of detecting not only the field strength but also the gradient of the field. For this purpose, at least two individual magnetometer units arranged at different spatial locations can be used and their signals can be calculated together.

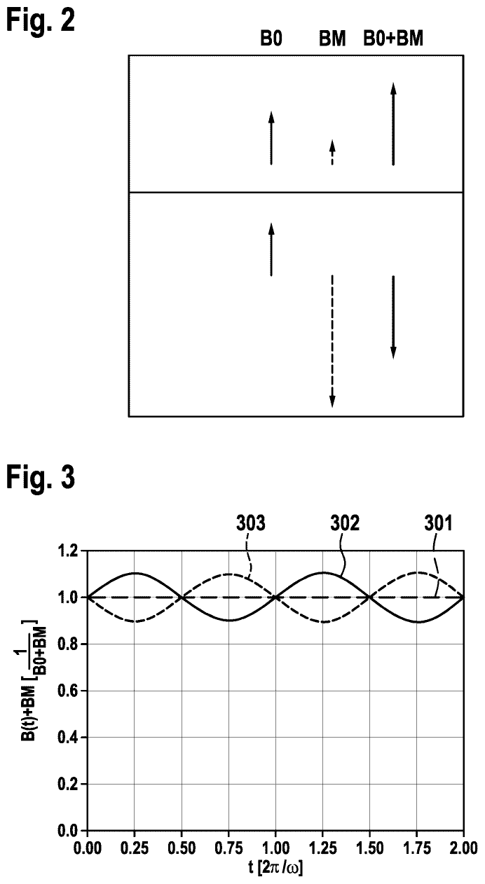

FIG. 2 shows an example of magnetic fields BM to be measured that conventionally cannot be distinguished when using a static bias magnetic field B0. This is because, in principle, a distinction between magnetic fields parallel and antiparallel to the bias magnetic field cannot be made with such a NV magnetometer unit. Such a distinction can be made on the basis of the magnetic field strength if the resulting field B0+BM is smaller than the bias magnetic field B0 (since the field to be measured must necessarily be antiparallel in this case). However, if the resulting field B0+BM is larger than the bias magnetic field B0, a distinction between a “small” (smaller than B0) parallel and a “large” (larger than B0) antiparallel field BM to be measured cannot be made.

Thus, if the measured resulting field B0+BM (right arrows) is larger than B0 (left arrows) and parallel or antiparallel to B0, the field BM (middle arrows) to be measured may be either parallel to the bias magnetic field B0 and smaller than B0 (upper diagram in FIG. 2) or antiparallel to the bias magnetic field B0 and larger than B0 (lower diagram in FIG. 2).

This can be solved through a time-varying component in the bias magnetic field, wherein the entire bias magnetic field B(t) is now composed of a constant component B0 and a time-varying component Bmod:

$$B ( t ) = B 0 + B mod sin ( ω t + φ )$$

since the orientation can then be determined unambiguously from the sign of the temporal change (addition for parallel and subtraction for anti-parallel) or from the phase of the measured signal BM+B(t) in relation to the phase o of the generated modulation, as shown in FIG. 3, in which the measured signal BM+B(t) is plotted over time.

301 denotes the measurement curve without modulation, in which a distinction between the two aforementioned cases cannot be made. 302 and 303 denote the measurement curves with modulation, which are phase-shifted by 180° to each other, depending on the direction of the resulting field in comparison to the time-varying component. If the field to be measured is smaller than B0 and parallel, the phase of the measured field corresponds to that of the modulation. If the field to be measured is larger than B0 and antiparallel, the phase of the measured field is shifted by 180° relative to the phase of the modulation.

For example, the bias magnetic field components may be generated by corresponding currents in a coil assembly. Accordingly, a current for generating this bias magnetic field is composed, for example, as follows:

$$I ( t ) - I 0 + I mod sin ( ω t + φ )$$

The amplitude of the slowly varying magnetic field component may be comparatively small, for example only corresponding to a small component of the static magnetic field, and the frequency may be in a range of 10 Hz to 10 kHz, for example.

Instead of a static current 10 generating the static magnetic field component B0 by means of a coil, the static magnetic field component B0 may also be generated at least partially by an arrangement of permanent magnets.

With the idea presented here, it can thus be reliably identified whether the magnetic field to be measured has possibly exceeded a certain amplitude and points in a different direction. It can thus also be used to provide an unambiguous plausibility check. This may be a mandatory requirement, in particular in safety-relevant applications of the magnetic field sensor, e.g., in the automotive industry.

1-8. (canceled)

9. A magnetometer unit configured to measure a magnetic field, comprising:
a sensor medium configured to be exposed to the magnetic field to be measured;
an excitation light source configured to irradiate light into the sensor medium;
a microwave source configured to generate an electromagnetic field in the sensor medium; and
a device configured to generate a bias magnetic field in a region of the sensor medium;
wherein the magnetometer unit is configured to detect a magnetic field strength and direction of the magnetic field to be measured, by reading out a spin resonance in the sensor medium that is dependent on the magnetic field strength and direction, and
wherein the device configured to generate the bias magnetic field is configured to generate a bias magnetic field having a constant component and a time-varying component.

10. The magnetometer unit according to claim 9, wherein an amplitude of the time-varying component is less than 50%.

11. The magnetometer unit according to claim 9, wherein the time-varying component follows a periodic function.

12. The magnetometer unit according to claim 11, wherein the periodic function is a sine function.

13. The magnetometer unit according to claim 11, wherein a fundamental frequency of the time-varying component is at least 10 Hz and/or at most 10 kHz.

14. The magnetometer unit according to claim 11, wherein the sensor medium is a diamond crystal or a portion of a diamond crystal with nitrogen-vacancy centers.

15. A gradiometer unit, comprising:
at least two magnetometer units, each configured to measure a magnetic field and each including:
a sensor medium configured to be exposed to the magnetic field to be measured,
an excitation light source configured to irradiate light into the sensor medium,
a microwave source configured to generate an electromagnetic field in the sensor medium, and
a device configured to generate a bias magnetic field in a region of the sensor medium,
wherein the magnetometer unit is configured to detect a magnetic field strength and direction of the magnetic field to be measured, by reading out a spin resonance in the sensor medium that is dependent on the magnetic field strength and direction, and
wherein the device configured to generate the bias magnetic field is configured to generate a bias magnetic field having a constant component and a time-varying component; and
a signal processing unit configured to ascertain a magnetic field gradient from the magnetic field strengths and directions of the magnetic field to be measured that are detected by the at least two magnetometer units.

16. The gradiometer unit according to claim 15, wherein the sensor medium of each of the at least two magnetometer units includes a portion of the same diamond crystal.

17. The gradiometer unit according to claim 15, wherein the at least two magnetometer units have the same excitation light source and/or the same microwave source.
